(19) United States
(12) Patent Application Publication
(10) Pub. No.: US 2025/0343524 A1
(43) Pub. Date: Nov. 6, 2025

(54) BALUN FOR POWER AMPLIFIER

(71) Applicant: Qorvo US, Inc., Greensboro, NC (US)

(72) Inventors: Yazid Yusuf, Orlando, FL (US); Kalyan Karnati, Apopka, FL (US)

(21) Appl. No.: 19/052,422

(22) Filed: Feb. 13, 2025

Related U.S. Application Data
(60) Provisional application No. 63/642,954, filed on May 6, 2024.

(51) Int. Cl. H03H 7/42; H03H 3/02; H03H 9/54; H04B 1/44

(52) U.S. Cl. CPC H03H 7/425; H03H 3/02; H03H 9/54; H04B 1/44

(57) ABSTRACT

A balun for a power amplifier is disclosed. In one aspect, a balun based on acoustic coupled resonator filters (CRFs) has a 4:1 impedance ratio between an unbalanced side and a balanced side. As such, the balun is well suited for use between power amplifiers and filters. The 4:1 ratio is achieved through one or more design options, including material selection, material thickness selection, series versus shunt inductor positions, CRF topology selection, or the like. The overall size is reduced relative to non-CRF baluns providing more room in a mobile device for other components or batteries.

### PRIORITY APPLICATION

The present application is related to U.S. Provisional Patent Application Ser. No. 63/642,954, filed on May 6, 2024, and entitled “BALUN FOR POWER AMPLIFIER,” the contents of which are incorporated herein by reference in its entirety.

### BACKGROUND

### I. Field of the Disclosure

The technology of the disclosure relates generally to a balun that impedance matches well for a power amplifier.

### II. Background

Computing devices abound in modern society, and more particularly, mobile communication devices have become increasingly common. The prevalence of these mobile communication devices is driven in part by the many functions that are now enabled on such devices. Increased processing capabilities in such devices means that mobile communication devices have evolved from pure communication tools into sophisticated mobile entertainment centers, thus enabling enhanced user experiences. With the advent of the myriad functions available to such devices, there has been increased pressure to find ways to shrink the component size to reduce the overall size of the device and maximize the space available for a battery. This pressure to reduce the size of components provides room for innovation.

### SUMMARY

Aspects disclosed in the detailed description include a balun for a power amplifier. In particular, a balun based on acoustic coupled resonator filters (CRFs) is disclosed. The balun may have a 4:1 impedance ratio between an unbalanced side and a balanced side. As such, the balun is well suited for use between differential power amplifiers and filters. The 4:1 ratio is achieved through one or more design options, including material selection, material thickness selection, series versus shunt inductor matching, CRF topology selection, or the like. The overall size is reduced relative to non-CRF baluns providing more room in a mobile device for other components or batteries.

In this regard, in one aspect, a balun is disclosed. The balun includes a single-ended unbalanced port having a first impedance and a differential balanced port having a second impedance, wherein the first impedance is approximately four times greater than the second impedance. The balun also includes a first CRF pair coupled in series to the single-ended unbalanced port and a second CRF pair coupled in series to the single-ended unbalanced port wherein the first CRF pair and the second CRF pair are coupled in parallel to the differential balanced port.

In another aspect, a wireless communication device is disclosed. The wireless communication device includes a transmitter comprising a power amplifier comprising a differential output and a filter comprising a single-ended input. The wireless communication device also includes a balun connecting the power amplifier and the filter, the balun comprising a single-ended unbalanced port having a first impedance, the single-ended unbalanced port coupled to the single-ended input and a differential balanced port having a second impedance, wherein the first impedance is approximately four times greater than the second impedance, the differential balanced port coupled to the differential output. The wireless communication device further includes a first CRF pair coupled in series to the single-ended unbalanced port and a second CRF pair coupled in series to the single-ended unbalanced port wherein the first CRF pair and the second CRF pair are coupled in parallel to the differential balanced port.

In another aspect, a method of forming a balun. The method includes identifying a desired impedance ratio, assembling CRF blocks to provide desired ratio, and coupling a resonator within the CRF blocks to a single ended port.

### BRIEF DESCRIPTION OF THE DRAWINGS

FIG. 1 is a block diagram of part of a transmitter having a balun therein;

FIG. 2A is a side cross-sectional view of an acoustic coupled resonator filter (CRF) building block highlighting the use of different materials to achieve impedance variation that may be used in aspects of the present disclosure;

FIG. 2B is a circuit diagram equivalent to the CRF building block of FIG. 2A with additional matching inductors shown;

FIG. 3A is a side cross-sectional view of an acoustic CRF building block highlighting different thicknesses of materials used in acoustic CRF that may be used in aspects of the present disclosure;

FIG. 3B is a circuit diagram equivalent to the CRF building block of FIG. 3A with additional matching inductors shown;

FIG. 4 is a circuit diagram of another CRF building block using series versus shunt inductors that may be used in aspects of the present disclosure;

FIG. 5 is a circuit diagram of another CRF building block that may be used in aspects of the present disclosure;

FIG. 6A is a CRF-based balun according to aspects of the present disclosure that provides a 4:1 ratio between unbalanced and balanced sides, respectively;

FIG. 6B is the CRF-based balun of FIG. 6A without an inverted piezoelectric material;

FIG. 7A is an alternate CRF-based balun according to aspects of the present disclosure using different piezoelectric materials and a series/shunt arrangement;

FIG. 7B is a circuit diagram of the alternate CRF-based balun of FIG. 7A;

FIG. 8A is another alternate CRF-based balun according to aspects of the present disclosure;

FIG. 8B is the CRF-based balun of FIG. 8A without an inverted piezoelectric material;

FIG. 9 is a flowchart illustrating an exemplary process for using a balun of the present disclosure; and

FIG. 10 is a block diagram of a communication device, which may include the CRF-based baluns of FIGS. 6A-8B according to the present disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that although the terms first, second, etc. may be used herein to describe various elements, these elements should not be limited by these terms. These terms are only used to distinguish one element from another. For example, a first element could be termed a second element, and similarly, a second element could be termed a first element without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element, or intervening elements may also be present. In contrast, when an element is referred to as being “directly on” or extending “directly onto” another element, no intervening elements are present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, no intervening elements are present. It will also be understood that when an element is referred to as being “connected” or “coupled” to another element, it can be directly connected or coupled to the other element, or intervening elements may be present. In contrast, when an element is referred to as being “directly connected” or “directly coupled” to another element, no intervening elements are present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

In keeping with the above admonition about definitions, the present disclosure uses transceiver in a broad manner. Current industry literature uses “transceiver” in two ways. The first way uses transceiver broadly to refer to a plurality of circuits that send and receive signals. Exemplary circuits may include a baseband processor, an up/down conversion circuit, filters, amplifiers, couplers, and the like coupled to one or more antennas. A second way, used by some authors in the industry literature, refers to a circuit positioned between a baseband processor and a power amplifier circuit as a transceiver. This intermediate circuit may include the up/down conversion circuits, mixers, oscillators, filters, and the like but generally does not include the power amplifiers. As used herein, the term transceiver is used in the first sense. Where relevant to distinguish between the two definitions, the terms “transceiver chain” and “transceiver circuit” are used respectively.

Additionally, to the extent that the term “approximately” is used in the claims,

it is herein defined to be within five percent (5%).

Aspects disclosed in the detailed description include a balun for a power amplifier. In particular, a balun based on acoustic coupled resonator filters (CRFs) is disclosed. The balun may have a 4:1 impedance ratio between an unbalanced side and a balanced side. As such, the balun is well suited for use between differential power amplifiers and filters. The 4:1 ratio is achieved through one or more design options, including material selection, material thickness selection, series versus shunt inductor matching, CRF topology selection, or the like. The overall size is reduced relative to non-CRF baluns providing more room in a mobile device for other components or batteries.

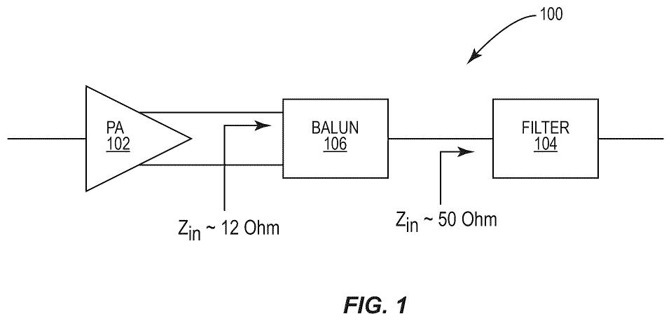

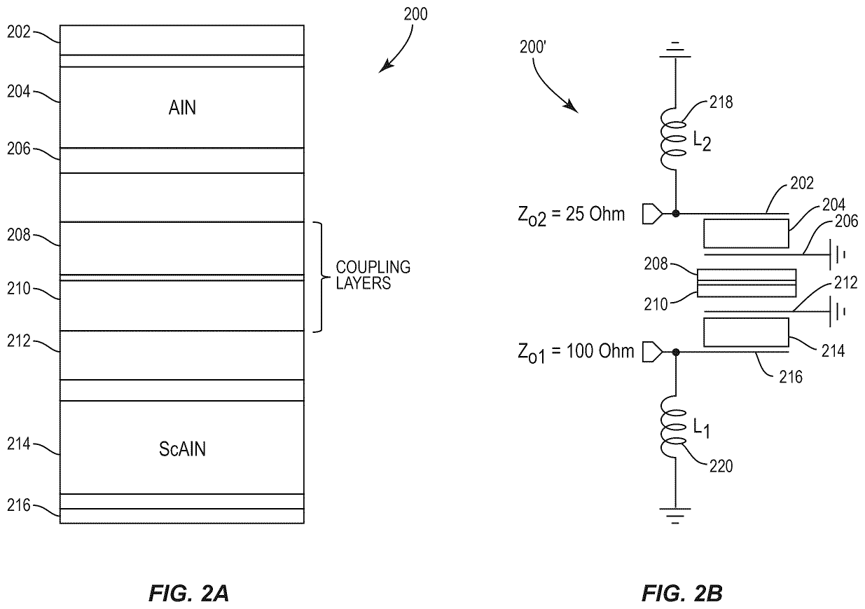

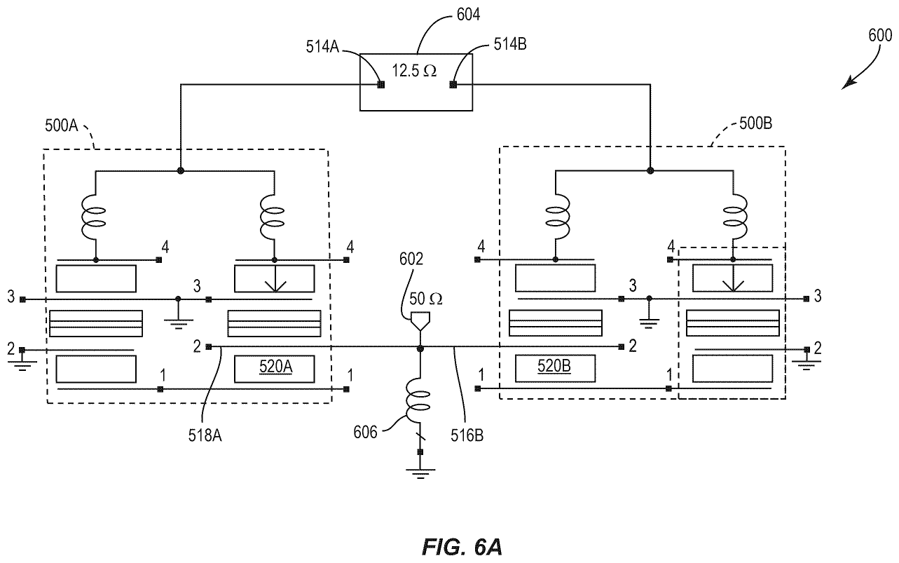

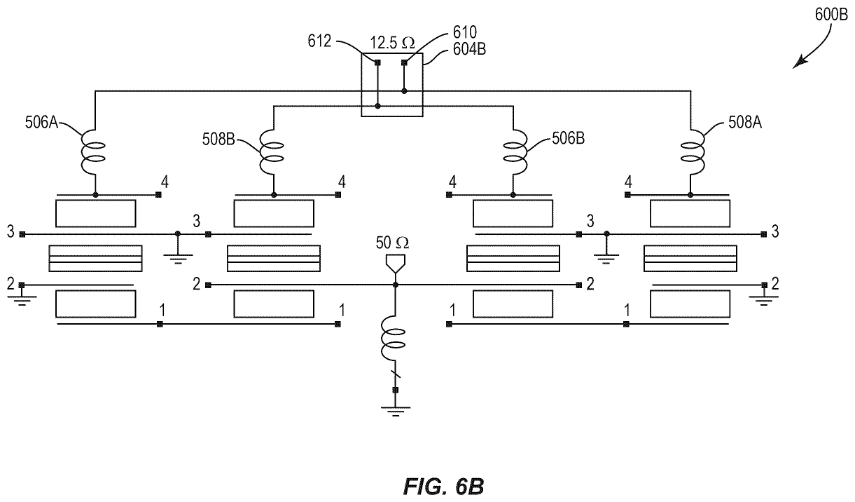

Before addressing aspects of the present disclosure, a brief contextual diagram is provided with reference to FIG. 1, showing where such a balun may be positioned in a transmitter. Various building blocks for an acoustic CRF-based balun are discussed with reference to FIGS. 2A-5. A discussion of acoustic CRF-based baluns is provided below, beginning with reference to FIG. 6A. Further, the concept of a CRF pair is also discussed, and how it may be used to advantage.

In this regard, FIG. 1 provides a block diagram of a transmitter 100 having a differential-ended power amplifier 102 and a singled-ended filter 104 with a balun 106 positioned therebetween to transform a differential end of the transmission chain at the output of the power amplifier 102 to a single-ended input of the filter 104. Additionally, the balun 106 may provide a desired impedance matching between the differential-ended power amplifier 102 and the filter. In an exemplary aspect, the balun may have a 4:1 impedance ratio between the balanced side facing the filter 104 and the unbalanced side facing the power amplifier 102 (i.e., 4U:1B, where U stands for unbalanced and B stands for balanced).

In the past, such a balun might have been made using coupled inductors in a laminate. An inductor-based approach would be bulky. Such an approach is becoming commercially impractical as manufacturers place increasing pressure on designers to reduce component size.

Aspects of the present disclosure use multiple acoustic CRF building blocks to form a balun that does not rely on inductors and thus may be smaller as dictated by commercial pressures. The use of CRF building blocks may also provide additional rejection in the stopbands based on their filtering characteristics. Before addressing the baluns, a few of the CRF building blocks are discussed with reference to FIGS. 2A-5.

In this regard, FIGS. 2A and 2B illustrate a first CRF building block 200 and its equivalent circuit diagram 200′ that can achieve an impedance ratio by varying the piezoelectric material used in coupled acoustic resonators. More specifically, the CRF building block 200 is formed by two acoustic resonators coupled together to form a stack. The first acoustic resonator has a first top electrode 202, a first piezoelectric material layer 204, and a first bottom electrode 206. In general, a top electrode such as the first top electrode 202 may be a plurality of metal layers on top of the piezoelectric material. For example, there may be two topmost metal layers in the stack that form the top electrode 202. Coupling layers 208, 210 join the first acoustic resonator to the second acoustic resonator, where the second acoustic resonator has a second top electrode 212, a second piezoelectric material layer 214, and a second bottom electrode 216.

The equivalent circuit diagram 200′ is provided in FIG. 2B with additional matching inductors, where similar elements are so-labeled. By varying the piezoelectric material used for layers 204, 214 an impedance transformation between the input and output ports may be created. In an exemplary aspect, the first material is a piezoelectric material with a first electromechanical coupling (e.g., aluminum nitride (AlN)), and the second material is different piezoelectric material with a second (different) electromechanical coupling (e.g., scandium aluminum nitride (ScAlN)). Note also that FIG. 2B illustrates two shunt inductors 218, 220, which couple electrodes 216 and 202 respectively to ground.

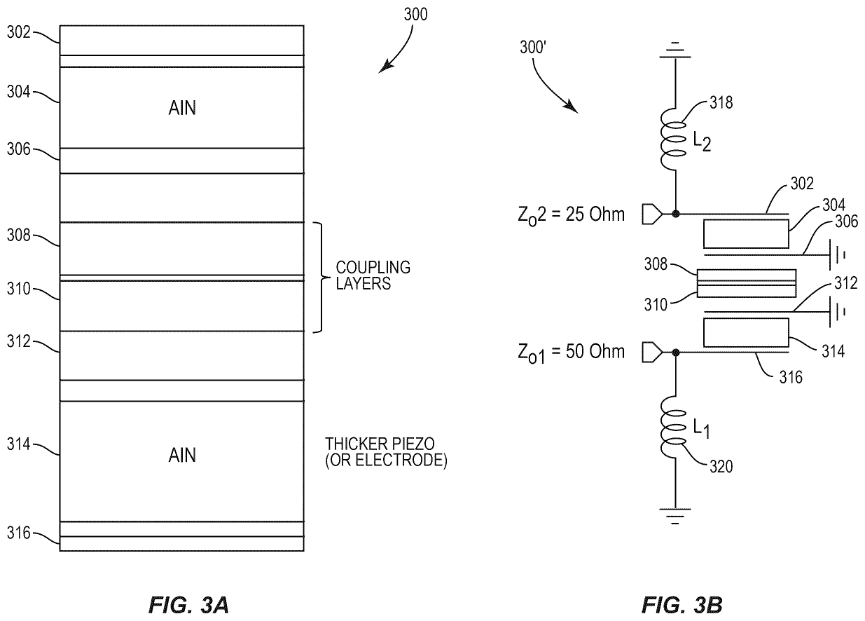

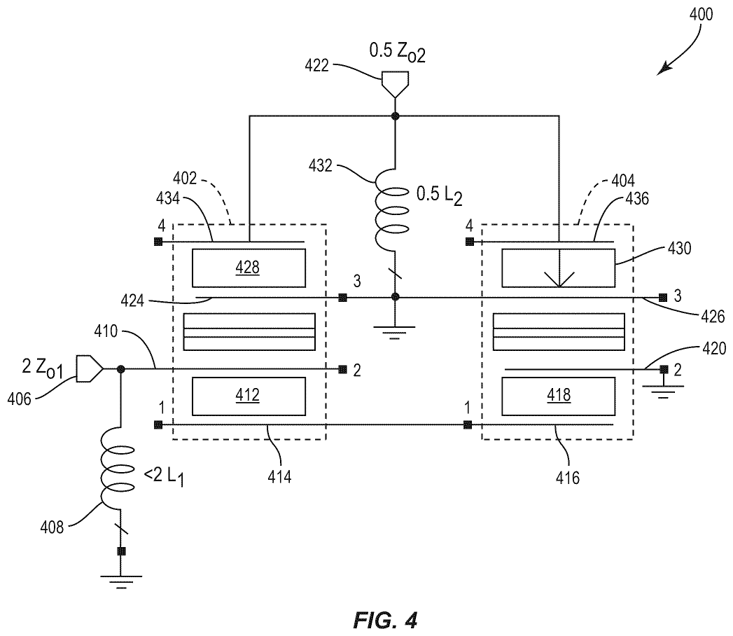

Alternatively, instead of varying the piezoelectric material, an impedance transformation may be effectuated by varying thicknesses of the piezoelectric material and/or the thicknesses of the electrodes. FIG. 3A provides a cross-sectional view of a CRF building block 300 formed by two acoustic resonators coupled together to form a stack. The first acoustic resonator has a first top electrode 302, a first piezoelectric material layer 304, and a first bottom electrode 306. Coupling layers 308, 310 join the first acoustic resonator to the second acoustic resonator, where the second acoustic resonator has a second top electrode 312, a second piezoelectric material layer 314, and a second bottom electrode 316. The equivalent circuit diagram 300′ is provided in FIG. 3B with additional matching inductors. As shown, the piezoelectric materials of the layers 304, 314 are the same material (e.g., AlN), but the thickness of the second piezoelectric material layer 314 is thicker than the thickness of the first piezoelectric material layer 304. Additionally, or alternatively, the electrodes 302, 306, 312, and 316 may be varied. Again, FIG. 3B includes shunt inductors 318, 320, which couple electrodes 302, 316 respectively to ground.

FIG. 4 illustrates another technique to alter impedance between ports using series and shunt connections between two CRFs. Specifically, FIG. 4 illustrates a paired CRF building block 400 having a first CRF block 402 and a second CRF block 404. A first port 406 is coupled to ground through an inductor 408 as well as coupling to a top electrode 410 of a first bottom resonator 412. Bottom electrodes 414 and 416 of the first bottom resonator 412 and a second bottom resonator 418 are shorted together. A second top electrode 420 of the second bottom resonator 418 is coupled to ground. This arrangement makes a series connection from the first port 406 through the two resonators 412, 418. The series connection gives an effective increase in the perceived impedance by a factor of two (since it sums the impedances of the two resonators 412, 418). The coupling layers are present in FIG. 4 but not labeled to prevent cluttering the diagram.

Conversely, at a second port 422 the CRF blocks 402 and 404 are coupled in parallel, which provides a reduction in impedance by a factor of two. Together, the increased impedance at first port 406 and the decreased impedance at second port 422 may provide a different impedance transformation ratio. Returning to the second port 422, bottom electrodes 424 and 426 of the top resonators 428 and 430 are coupled to ground as well as being coupled to the second port 422 through an inductor 432. Top electrodes 434 and 436 of the two top resonators 428, 430 are also coupled to the second port 422.

Note that to get the signals to combine constructively, one of the piezoelectric materials in a resonator has an inverted polarity. As illustrated, the top resonator 430 is so inverted (as indicated by the internal arrow in the top resonator 430). Note also that there is some capacitance formed between top and bottom resonators within a building block 402,404. Specifically, there could be a capacitance between the top electrode 420 and the bottom electrode 426, but since both are coupled to ground, this capacitance does not contribute to the circuit. However, there is a capacitance between the top electrode 410 and the bottom electrode 424. The value of the inductor 408 may be selected to offset this capacitance.

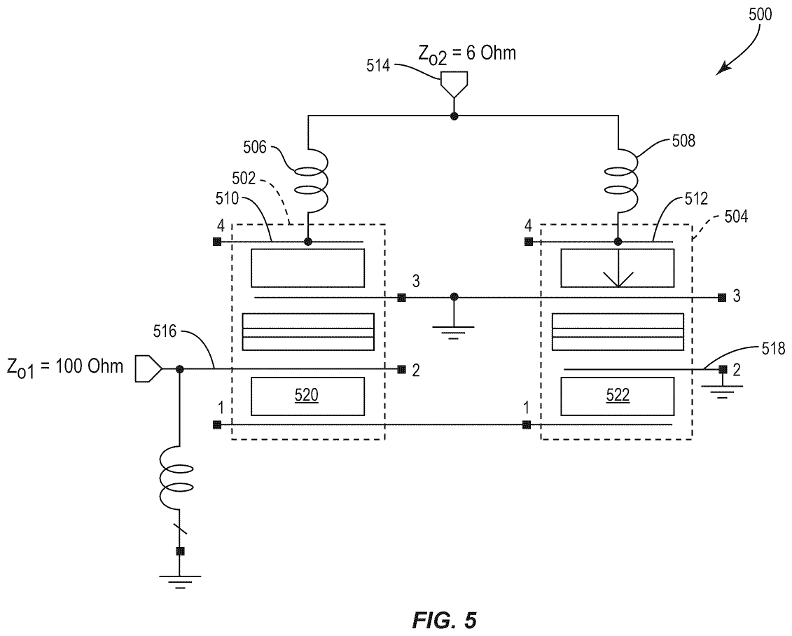

FIG. 5 illustrates a paired CRF building block 500 that combines a few previously illustrated approaches to get a 16:1 ratio. Specifically, the paired CRF building block 500 includes a first CRF block 502 and a second CRF block 504, which are coupled together substantially similar to paired CRF building block 400, but instead of the inductor 432 coupling the second port 422 to ground, inductors 506, 508 serially couple top electrodes 510, 512 to a second port 514. The addition and arrangement of these inductors 506, 508 reduces the impedance of the second port 514 by another factor of two. If the CRF blocks 502 and 504 include asymmetric materials or thicknesses (either in the piezoelectric material and/or in the electrode thicknesses as explained above with reference to FIGS. 2A and 3A), another factor of two impedance transformation can be achieved, thereby providing the 16:1 ratio (e.g., 100 ohms to 6 ohms as shown in FIG. 5). Top electrodes 516, 518 are positioned on the bottom resonators 520, 522 and are discussed in greater detail below.

As used herein, a paired CRF building block is equivalent to a CRF pair and is defined to be a first acoustic resonator coupled in series to a second acoustic resonator such that a bottom electrode of a first acoustic resonator is positioned on top of a top electrode of a second acoustic resonator with one or more coupling layers positioned therebetween. In this regard, FIGS. 2A and 3A show a CRF pair. When two CRF pairs are put together, that structure is defined herein to be a CRF doublet. The authors recognize that this term is not an industry term and thus provide this explicit definition to use with the appended claims.

Using the building blocks illustrated above, it is possible to create baluns with a desired impedance ratio, as seen in FIGS. 6A-8B. In this regard, FIG. 6A illustrates an exemplary balun 600 that combines two CRF doublets 500A and 500B (each having two CRF pairs) between a single-ended port 602 having a high impedance (e.g., 50 ohms for the filter 104) and a differential port 604 having a low impedance (e.g., 12 ohms for the power amplifier 102). The single-ended port 602 couples to the two CRF doublets 500A, 500B at a node that connects an inductor 606 and top electrodes 518A, 516B of the bottom resonators 520A, 520B. The differential port 604 is formed from the second ports 514A, 514B. This arrangement does have the inverted piezoelectric material in each building doublet 500A, 500B. Notice, however, that the location of the resonator with inverted polarity in the two doublets 500A and 500B is different with respect to the single-ended port, which is necessary to create a 180-degree phase difference between the signals at 514A and 514B and the desired operation as a balun.

In contrast, FIG. 6B illustrates an alternate structure for exemplary balun 600B for the differential port 604B that allows the elimination of the inverted piezoelectric material. Specifically, inductor 506A is coupled to inductor 508B to form a first end 610, and inductor 506B is coupled to inductor 508A to form a second end 612. Collectively ends 610, 612 form the differential port 604B. In either case, the 4U:1B ratio is provided for the balun.

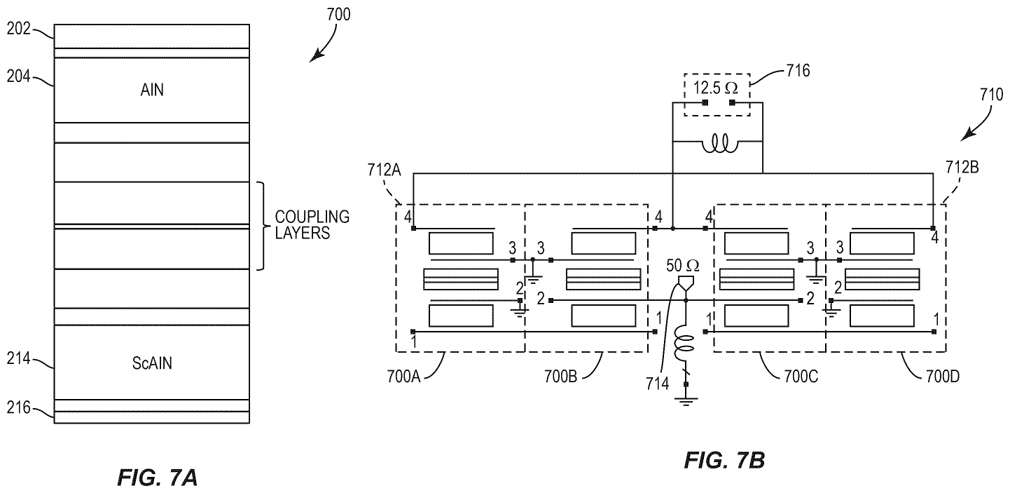

FIG. 7A revisits a CRF pair 700 that is similar to CRF building block 200, including not only different piezoelectric materials, but also including different thicknesses for the piezoelectric material layers, i.e., the second piezoelectric material layer 214 is thicker than piezoelectric material layer 204 so that a desired impedance may be created in the exemplary balun 710 illustrated in FIG. 7B. The exemplary balun 710 uses CRF doublets 712A, 712B that are formed from CRF pairs 700A-700D. The CRF doublets 712A, 712B are coupled using the series/shunt arrangement of FIGS. 4 and 6B so that there is a single-ended port 714 and a differential-ended port 716 without the need for inverted piezoelectric material.

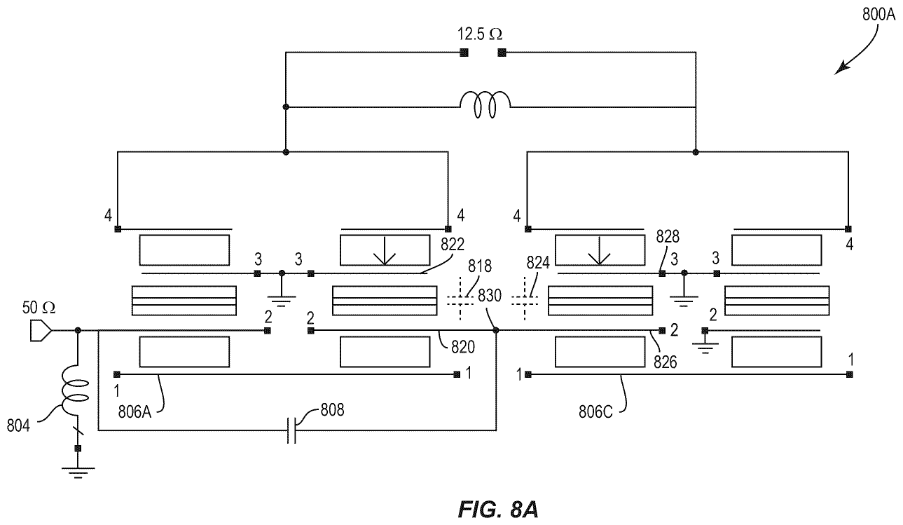

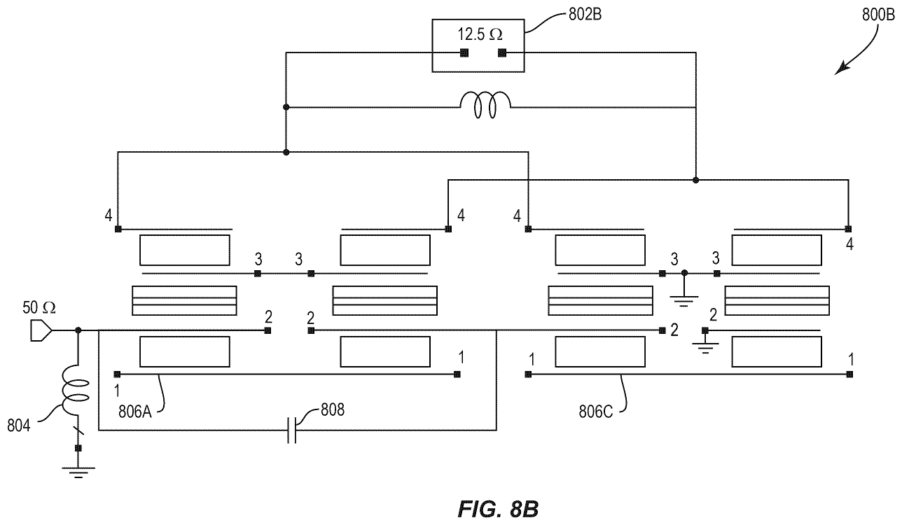

FIGS. 8A and 8B illustrate exemplary baluns 800A, 800B, respectively, that differ in that in balun 800A, there is an inverting piezoelectric material, and in balun 800B, there is not by virtue of the different parallel combinations to form the differential-ended port 802B. The baluns 800A, 800B differ from previous baluns described in that four resonators are cascaded in series at the unbalanced side. As with FIG. 4, a capacitance 818 may be formed between a top electrode 820 and a bottom electrode 822. A similar capacitance 824 may be formed between top electrode 826 and bottom electrode 828. To balance the capacitance, a balancing capacitor 808 is added. Alternatively, an inductor (not shown) may be added to shunt the node 830 to ground.

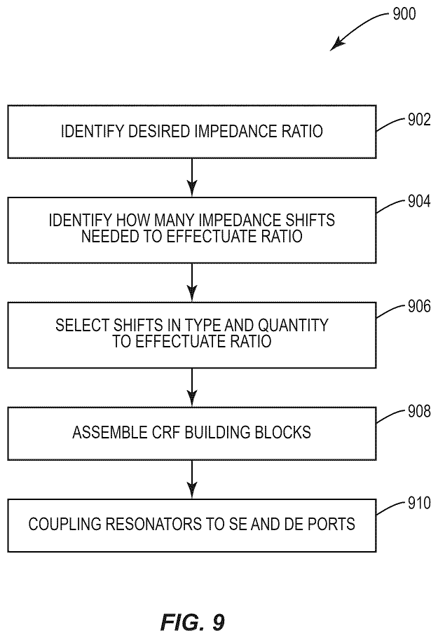

A process 900 of forming a balun according to aspects of the present disclosure is set forth in FIG. 9. The process 900 begins with an identification of a desired impedance ratio (block 902). This ratio is based on an output impedance from the power amplifier 102 (typically low, around 12 ohms) and the input impedance of the filter 104 (typically high, around 50 ohms). Thus, it is common to need a 4U:1B impedance ratio, although other ratios may be accommodated. The process 900 continues by identifying how many impedance shifts are needed to effectuate the ratio (block 904). Shifts are selected in type and quantity that effectuate the ratio (block 906). This selection may be based on available manufacturing processes. For example, changing piezoelectric material may be commercially impractical, and thus, a CRF building block 700 may be inappropriate. Likewise, having an inverted piezoelectric material layer may be impractical, and thus, the parallel structures of FIG. 6B or 8B may be more practical.

The process 900 continues by assembling CRF building blocks (block 908) and coupling the resonators to single-ended and differential-ended ports (block 910).

The balun for power amplifiers according to aspects disclosed herein, may be provided in or integrated into any processor-based device that likely includes a communication circuit. Examples, without limitation, include a set-top box, an entertainment unit, a navigation device, a communications device, a fixed location data unit, a mobile location data unit, a global positioning system (GPS) device, a mobile phone, a cellular phone, a smartphone, a session initiation protocol (SIP) phone, a tablet, a phablet, a server, a computer, a portable computer, a mobile computing device, a wearable computing device (e.g., a smartwatch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, a drone, and a multicopter.

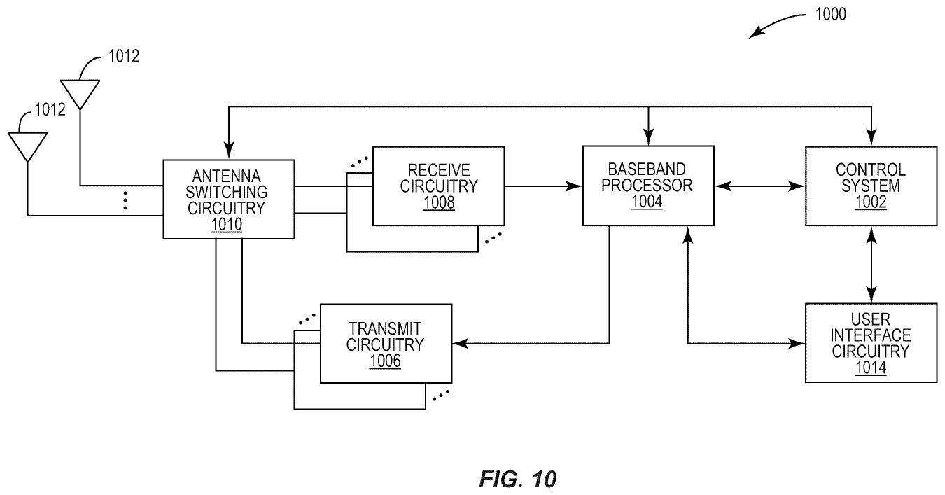

FIG. 10 is a schematic diagram of an exemplary communication device 1000 wherein the baluns of the present disclosure can be provided. Herein, the communication device 1000 can be any type of communication device, wired (not shown) or wireless, such as those listed above, as well as access points, base stations (e.g., eNB or gNB), and any other type of wireless communication devices that support wireless communications, such as cellular, wireless local area network (WLAN), Bluetooth, Ultra-wideband (UWB), and near field communications.

More particularly, the communication device 1000 will generally include a control system 1002, a baseband processor 1004, transmit circuitry 1006, receive circuitry 1008, antenna switching circuitry 1010, multiple antennas 1012, and user interface circuitry 1014. In a non-limiting example, the control system 1002 can be a field-programmable gate array (FPGA) or an application-specific integrated circuit (ASIC), as an example. In this regard, the control system 1002 can include at least a microprocessor(s), an embedded memory circuit(s), and a communication bus interface(s). The receive circuitry 1008 receives radio frequency signals via the antennas 1012 and through the antenna switching circuitry 1010 from one or more base stations. A low noise amplifier and a filter of the receive circuitry 1008 cooperate to amplify and remove broadband interference from the received signal for processing. Downconversion and digitization circuitry (not shown) will then downconvert the filtered, received signal to an intermediate or baseband frequency signal, which is then digitized into one or more digital streams using an analog-to-digital converter(s) (ADC).

The baseband processor 1004 processes the digitized received signal to extract the information or data bits conveyed in the received signal. This processing typically comprises demodulation, decoding, and error correction operations. The baseband processor 1004 is generally implemented in one or more digital signal processors (DSPs) and ASICs.

For transmission, the baseband processor 1004 receives digitized data, which may represent voice, data, or control information, from the control system 1002, which it encodes for transmission. The encoded data is output to the transmit circuitry 1006, where a digital-to-analog converter(s) (DAC) converts the digitally encoded data into an analog signal, and a modulator modulates the analog signal onto a carrier signal that is at a desired transmit frequency or frequencies. A power amplifier that may be coupled to a filter through a balun of the present disclosure will amplify the modulated carrier signal to a level appropriate for transmission and deliver the modulated carrier signal to the antennas 1012 through the antenna switching circuitry 1010 to the antennas 1012. The multiple antennas 1012 and the replicated transmit and receive circuitries 1006, 1008 may provide spatial diversity. Modulation and processing details will be understood by those skilled in the art.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications, as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein but is to be accorded the widest scope consistent with the principles and novel features disclosed herein.

What is claimed is:

1. A balun comprising:
a single-ended unbalanced port having a first impedance;
a differential-balanced port having a second impedance, wherein the first impedance is approximately four times greater than the second impedance;
a first coupled resonator filter (CRF) doublet coupled in series to the single-ended unbalanced port; and
a second CRF doublet coupled in series to the single-ended unbalanced port; and
wherein the first CRF doublet and the second CRF doublet are coupled in parallel to the differential-balanced port.

2. The balun of claim 1, wherein the first CRF doublet comprises a first resonator having a first piezoelectric material layer that is thicker than a second piezoelectric material in a second resonator.

3. The balun of claim 1, wherein the first CRF doublet comprises a first resonator having a first piezoelectric material layer having a first electromechanical coupling and a second resonator having a second piezoelectric material having a second electromechanical coupling different from the first.

4. The balun of claim 1, wherein the second CRF doublet comprises at least one inverted polarity piezoelectric material layer for constructive combination at the differential-balanced port.

5. The balun of claim 1, wherein a first CRF pair of the first CRF doublet and a third CRF pair of the second CRF doublet are coupled to form part of the differential-balanced port and a second CRF pair of the first CRF doublet and a fourth CRF pair of the second CRF doublet are coupled to form another part of the differential-balanced port.

6. The balun of claim 1, further comprising a shunt inductor coupling the single-ended unbalanced port to ground.

7. The balun of claim 6, wherein the shunt inductor compensates for a first capacitance formed in a first CRF pair of the first CRF doublet.

8. The balun of claim 7, further comprising a balancing capacitor coupling the single-ended unbalanced port to a node between the first CRF doublet and the second CRF doublet.

9. A wireless communication device comprising:
a transmitter comprising:
a power amplifier comprising a differential output;
a filter comprising a single-ended input; and
a balun connecting the power amplifier and the filter, the balun comprising:
a single-ended unbalanced port having a first impedance, the single-ended unbalanced port coupled to the single-ended input;
a differential-balanced port having a second impedance, wherein the first impedance is approximately four times greater than the second impedance, the differential-balanced port coupled to the differential output;
a first coupled resonator filter (CRF) doublet coupled in series to the single-ended unbalanced port; and
a second CRF doublet coupled in series to the single-ended unbalanced port; and
wherein the first CRF doublet and the second CRF doublet are coupled in parallel to the differential-balanced port.

10. The wireless communication device of claim 9, wherein the first CRF doublet comprises a first resonator having a first piezoelectric material layer that is thicker than a second piezoelectric material in a second resonator.

11. The wireless communication device of claim 9, wherein the first CRF doublet comprises a first resonator having a first piezoelectric material layer comprising aluminum nitride (AlN) and a second resonator having a second piezoelectric material layer comprising scandium aluminum nitride (ScAlN9).

12. The wireless communication device of claim 9, wherein the second CRF doublet comprises at least one inverted polarity piezoelectric material layer for constructive combination at the differential-balanced port.

13. The wireless communication device of claim 9, wherein a first CRF pair of the first CRF doublet and a third CRF pair of the second CRF doublet are coupled to form part of the differential-balanced port and a second CRF pair of the first CRF doublet and a fourth CRF pair of the second CRF doublet are coupled to form another part of the differential-balanced port.

14. The wireless communication device of claim 9, further comprising a shunt inductor coupling the single-ended unbalanced port to ground.

15. The wireless communication device of claim 14, wherein the shunt inductor compensates for a first capacitance formed in a first CRF pair of the first CRF doublet.

16. The wireless communication device of claim 15, further comprising a balancing capacitor coupling the single-ended unbalanced port to a node between the first CRF doublet and the second CRF doublet.

17. The wireless communication device of claim 9 integrated into a device selected from the group consisting of: a set-top box; an entertainment unit; a navigation device; a communications device; a fixed location data unit; a mobile location data unit; a global positioning system (GPS) device; a mobile phone; a cellular phone; a smartphone; a session initiation protocol (SIP) phone; a tablet; a phablet; a server; a computer; a portable computer; a mobile computing device; a wearable computing device; a desktop computer;
a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; avionics systems; a drone; and a multicopter.

18. A method of forming a balun, comprising:
identifying a desired impedance ratio;
assembling coupled resonator filter (CRF) blocks to provide desired ratio; and
coupling a resonator within the CRF blocks to a single ended port.

19. The method of claim 18, further comprising coupling a second resonator within the CRF blocks to a differential ended port.

20. The method of claim 18, further comprising identifying how many impedance shifts are needed to effectuate the desired impedance ratio.
